(19) United States
(12) Patent Application Publication
(10) Pub. No.: US 2003/0015715 A1
(43) Pub. Date: Jan. 23, 2003

(54) Gallium nitride-based light emitting device

(76) Inventor: Shiro Sakai, Tokushima-shi (JP)

Correspondence Address: Jonathan P. Osha, ROSENTHAL & OSHA L.L.P., 700 Louisiana, Suite 4550, Houston, TX, 77002, US

(21) Appl. No.: 10/184,382

(22) Filed: Jun. 27, 2002

(30) Foreign Application Priority Data
Jun. 29, 2001 (JP) 2001-198305

(51) Int. Cl. H01L 27/15

(52) U.S. Cl. 257/79

(57) ABSTRACT

A light emitting element having a GaN layer and a light emitting layer formed on a substrate. A GaN layer is formed on a substrate so as to form a Ga-based light emitting layer. An AlGaN layer having a refractive index smaller than that of the light emitting layer or Al composition larger than that of the light emitting layer (18) is formed between the GaN layer (14) and the light emitting layer (18). Light from the light emitting layer (18) is reflected at the boundary relative to the AlGaN layer (16), so that light absorption in the GaN layer (14) is suppressed.

### BACKGROUND OF THE INVENTION

1. Field of the Invention

The present invention relates to gallium nitride (GaN)-based light emitting device, and in particular to an LED having a GaN or AlGaN light-emitting layer.

2. Description of the Related Art

Galliumnitride (GaN)-based light emitting devices having a light emitting layer made of GaN or AlGaN have been widely applied in short wavelength (a band of 350 nm wavelength) LEDs and the like.

A short wavelength LED often includes a GaN layer having a layered structure with a thickness of 0.1 μm or greater. For example, a GaN layer may be grown on a substrate made of sapphire, SiC, or the like, and a device structure is the grown on the GaN layer. The GaN layer has an important function to reduce dislocation in the device structure. In particular, a GaN layer which reduces dislocation is very important in an LED having a GaN or AlGaN light emitting layer because light emission efficiency of the light emitting layer largely depends on dislocation density.

Although a GaN layer reduces dislocation density, its nature is such that it absorbs light in a wavelength band near 350 nm. This deteriorates light emitting efficiency of the device.

In addition, another proposed structure including an InGaN layer or the like, instead of a GaN layer, for reduction of dislocation density causes a problem that the InGaN layer absorbs light in a wavelength band around 350 nm, similar to a GaN layer.

Currently, reduction of dislocation density and improvement of light emitting efficiency cannot both be pursued at the same time.

### SUMMARY OF THE INVENTION

The present invention aims to provide a light emitting device having low dislocation density and high light emitting efficiency.

According to one aspect of the present invention, there is provided a light emitting device comprising a substrate; a GaN layer formed on the substrate; a light emitting layer formed on the GaN layer; and a GaN-based layer formed between the GaN layer and the light emitting layer and having a refractive index smaller than a refractive index of the light emitting layer.

According to another aspect of the present invention, there is provided a GaN-based light emitting device comprising a substrate; a GaN layer formed on the substrate; a light emitting layer formed on the layer; a GaN-based layer formed between the GaN layer and the light emitting layer and having Al composition larger than Al composition of the light emitting layer.

In the present invention, a GaN-based layer having a refractive index smaller than that of a light emitting layer or Al composition larger than that of a light emitting layer is formed between the light emitting layer and the GaN layer. This structure reduces dislocation density, so that absorption of light having emitted from the light emitting layer and reached the GaN layer is suppressed. Use of a larger Al composition for the GaN-based layer can decrease the layer's refractive index, which creates a difference in the refractive index at the boundary relative to the light emitting layer, such that light from the light emitting layer is thus reflected at the boundary. In one embodiment of the present invention, a GaN-based layer is formed both above and below the light emitting layer so as to sandwich the light emitting layer such that the light is enclosed within the light emitting layer. This arrangement can suppress light absorption in the GaN layer.

The GaN-based layer having Al composition which is larger than that of the light emitting layer can have a stacking structure constituting of AlGaN layers and GaN layers, instead of a single AlGaN layer. One embodiment of the present invention, a strained layer superlattice layer constituting of AlGaN layers and GaN layers may be employed. The average Al composition of the stacking structure, when used, is larger than that of the light emitting layer.

The present invention may be more clearly understood with reference to the following embodiments, but to which the scope of the present invention is not limited.

### BRIEF DESCRIPTION OF THE DRAWINGS

The above and other objects, features, and advantages of the present invention will become further apparent from the following description of the preferred embodiment taken in conjunction with the accompanying drawings wherein:

FIG. 1 is a diagram showing a structure of a UV-LED;

FIG. 2 is a diagram explaining operation of an embodiment; and

FIG. 3 is a diagram showing another structure of a UV-LED.

### DESCRIPTION OF THE PREFERRED EMBODIMENT

In the following, a preferred embodiment of the present invention will be described with reference to the drawings.

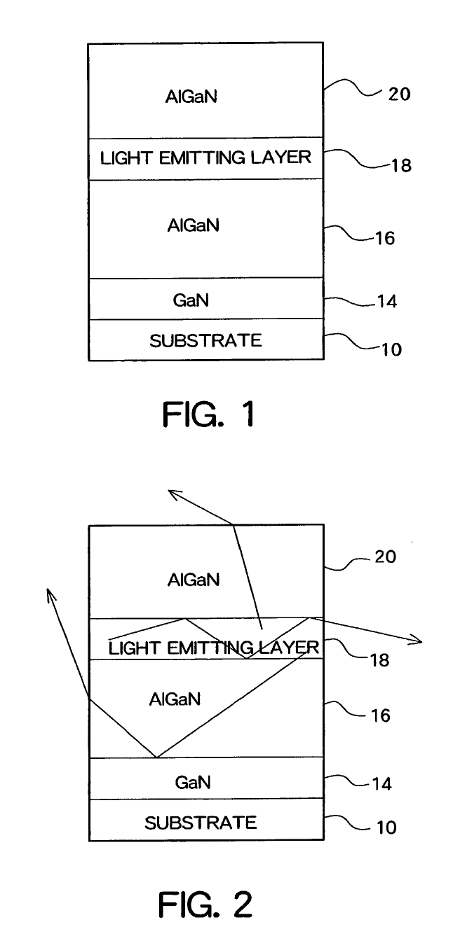

FIG. 1 is a diagram showing an LED (a UV-LED which emits UV light) in an embodiment of the present invention. Specifically, a GaN layer 14 is formed on a substrate 10 made of sapphire or the like, an AlGaN layer 16 is formed on the GaN layer 14, a light emitting layer 18, made of either GaN or AlGaN, is formed on the AlGaN layer 16, and an AlGaN layer 20 is formed on the light emitting layer 18. That is, the light emitting layer 18 is sandwiched by the AlGaN layer 16 and AlGaN layer 20. The AlGaN layer 16 is formed into an n-type and the AlGaN layer 20 is formed into a p-type, together constituting Pn junction. When AlGaN is used for the light emitting layer 18, Al composition of the AlGaN layers 16 and 20 is set to have a value larger than that of the light emitting layer 18. These AlGaN layers 16 and 20 are formed having an optically thick enough thickness, specifically, 0.1 μm or greater.

The thicknesses of these layers may be along the lines of 2 μm for the GaN layer 14, 0.5 μm for the AlGaN layers 16 and 20, and 10 nm for the light emitting layer 18.

The respective layers in FIG. 1 can be formed by placing a substrate 10 in an MOCVD and, while heating the substrate 10 using a heater, sequentially introducing reaction gas into the MOCVD. Specifically, a substrate 10 is placed in a reaction tube of an MOCVD and heated, and source gas, including trimethylgallium and ammonia gas, is then introduced into the reaction tube for growth of a GaN layer 14. Further, trimethylaluminium, trimethylgallium, and ammonia gas are introduced for sequential growth of an AlGaN layer.

It should be noted that, whereas the light emitting layer 18 in FIG. 1 is sandwiched by the AlGaN layers 16 and 20, for example, Si may be doped as a donor into the AlGaN layer 16, and Mg maybe doped as an acceptor into the AlGaN layer 20. While the respective layers are generally grown at, for example, approximately 1000° C., growth of the GaN layer 14 may begin with formation of a GaN buffer layer at a lower temperature (600° C. or lower). In order to function as a light emitting device, a p-electrode is formed in the AlGaN layer 20, an n-electrode is formed in the GaN layer 14, and both electrodes are connected to a power source. For connection of an n-electrode to the GaN layer 14, the surface of the grown layer is etched for partial removal such that GaN layer 14 is partially exposed.

In this embodiment, the light emitting layer 18 is sandwiched by the AlGaN layers 16 and 20, and the Al composition of the AlGaN layers 16 and 20 is set to have a value larger than that of the light emitting layer 18. As a larger Al composition ratio is known to reduce a refractive index, the emitting layer 18 is resultantly sandwiched by layers the refractive index of which is smaller than that of its own. As a result, light from the light emitting layer 18 is fully reflected at the boundaries between the light emitting layer 18 and the AlGaN layer 16 and between the light emitting layer 18 and the AlGaN layer 20, proceeding within the light emitting layer 18, as shown in FIG. 2. Also, light which should enter the AlGaN layer 16 is reflected at the boundary between the AlGaN layer 16 and the GaN layer 14. As a result, substantially no light from the light emitting layer 18 reaches the GaN layer 14, so that light absorption by the GaN layer 14 can be suppressed.

As the GaN layer 14 has an effect of reducing dislocation density of a layer formed thereon, as described above, in the light emitting device in this embodiment dislocation density can be reduced through this effect of the GaN layer 14, and, at the same time, suppress absorption of light (in a band of wavelength 350 mm) from the light emitting layer 18. This enables high light emitting efficiency.

In this embodiment, an InGaN layer may be additionally provided between the GaN layer 14 and the AlGaN layer 16, and the AlGaN layer 16 and the AlGaN layer 20 may respectively be formed as a strained layer superlattice, SLS, layer, in which AlGaN layers and GaN layers are alternately stacked, rather than as a single AlGa layer. An SLS layer can modify internal stress, thus suppressing cracks, and facilitate formation of a thick layer having a thickness 0.1 μm or greater.

It should be noted that, although the light emitting layer 18 is sandwiched by the AlGaN layers 16 and 20 in the above embodiment, the effect of preventing absorption in the GaN layer 14 of light from the light emitting layer can be achieved to some degree when at least an AlGaN layer 16 is provided between the GaN layer 14 and the light emitting layer 18, and therefore, in view of this effect, the AlGaN layer 20 may be omissible.

In the following, this alternate configuration of the embodiment will be described more specifically.

A light emitting device according to this configuration is produced through the following procedure. That is, an SiN and GaN buffer layer is formed at 500° C. on the substrate 10 having a sapphire C surface, an n-GaN layer 14 is further grown while increasing the temperature to 1070° C. Further, an n-SLS layer is grown at the same temperature, in which an Si-doped Al_{0.2}Ga_{0.8}N layer (2 nm) and an Si-doped GaN layer (2 nm) are alternately stacked. This SLS layer corresponds to the AlGaN layer 16 in FIG. 1. The AlGaN layer is grown using source gas of trimethylgallium, trimethylaluminium, and ammonia gas, and then doped with Si by introducing silane gas thereto.

After the growth of the n-SLS layer constituting of Si-doped AlGaN layers and Si-doped GaN layers, a light emitting layer 18 is grown thereon, which constitutes of an undoped Al_{0.1}Ga_{0.9}N layer (5 nm), a GaN layer (2 nm), and an undoped Al_{0.1}Ga_{0.9}N layer (5 nm).

After the growth of the light emitting layer 18, an Mg-doped Al_{0.2}Ga_{0.8}N layer (2 nm) and an Mg-doped GaN layer (1 nm) are alternately stacked in M cycles for growth of a p-SLS layer. This SLS layer corresponds to the AlGaN layer 20 in FIG. 1.

After the growth of the p-SLS layer constituting of Mg-doped AlGaN layers and Mg-doped GaN layers, an Mg-doped p-GaN layer (20 nm) is grown.

An MOCVD is used for the growth of these layers. Specifically, a sapphire substrate is mounted on a susceptor in a reaction tube, and heated to 1150° C. under H₂ atmosphere using a heater. Then, reaction gas is sequentially introduced into the tube via a gas introducing section so that these layers are grown. Thereafter, the surface of the layers is partially etched to the depth of reaching the n-SLS layer, and an n-electrode 26 and a p-electrode 24 are formed on the etched and unetched surfaces, respectively. Further, the layers are cut into chips, and each is mounted on a mount having a recessed mirror plane to thereby complete a UV-LED.

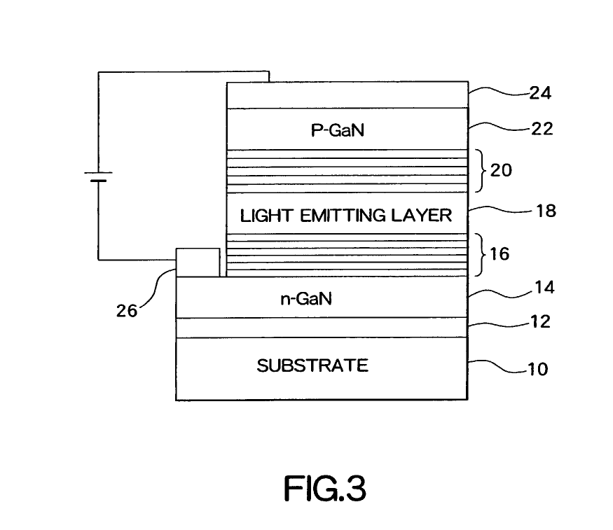

FIG. 3 is a diagram showing a structure of an UV-LED produced as described above. A buffer layer, namely, an SiN and GaN layer 12, is formed on the sapphire substrate 10 at a lower temperature, and an n-GaN layer 14 is formed thereon so as to have a thickness t (μm) at a higher temperature. It should be noted that the n-GaN layer 14 suppresses dislocation of a layer formed thereon. Formed on the n-GaN layer 14 are an n-SLS layer 16, and further a light emitting layer 18 comprising AlGaN and GaN and having a total thickness 12 nm. Then, a p-SLS layer 20 is formed on the light emitting layer 18, and a p-Gan layer 22 having a thickness 20 nm is further formed thereon. The average Al composition of the n-SLS layer 16 and the p-SLS layer 20 is larger than that of the light emitting layer 18. When positive bias is applied to between the p-GaN layer 22 and the n-GaN layer 24, UV light, that is, light of a wavelength band surrounding 350 nm, is emitted from the light emitting layer 18.

LEDs having a structure as described above are formed while changing a thickness t of the n-GaN layer 14, a stacking cycle N for the n-SLS layer 16, and a stacking cycle M for the p-SLS layer 20, and light emitting efficiency of such LEDs is measured. The measurement results are shown below.

TABLE

| | | n-SLS total | | p-SLS total | relative light |
|---|---|---|---|---|---|
| T (μm) | N | thickness (μm) | M | thickness (μm) | emitting intensity |
| 0.4 | 500 | 2 | 50 | 0.15 | 1 |
| 0.6 | 450 | 1.8 | 50 | 0.15 | 0.9 |
| 2 | 250 | 1 | 50 | 0.15 | 0.9 |
| 2 | 50 | 0.2 | 50 | 0.15 | 0.5 |
| 2 | 20 | 0.04 | 50 | 0.15 | 0.01 |

In any case, the emitting light peaks at a wavelength 351 nm. It should be noted that, although cracks are found on wafers of the samples with N being 450 and 250, that is, an n-SLS layer 16 having a total thickness 1.8 μm and 1 μm, LEDs are formed using a part of the layers where no crack is caused in the embodiment. The light emitting intensity is represented in a relative value with the maximum being 1.

As is understood from Table 1, the light emitting intensity sharply drops to a half or less of the maximum with an n-SLS layer 16 having a thickness smaller than approximately 0.1 μm. While the thickness t of the n-GaN layer 14 and that of the p-SLS layer 20 are unchanged, the light emitting intensity is larger for a thicker n-GaN layer 14. Though not shown in Table 1, a similar tendency is observed with the p-SLS layer 20, that is, light emitting intensity sharply drops for a thickness smaller than approximately 0.1 μm and increases for a larger thickness.

However, for N=500, that is, the thickness of the n-SLS layer 16 being 2 μm, cracks are observed with M being 100, that is, when the thickness of the p-SLS layer 20 is 0.3 μm or greater.

As described above, in a structure in which a GaN layer 14 is formed on a substrate, a drop in light emitting efficiency due to light absorption in the GaN layer 14 can be suppressed through provision of an n-SLS layer 16 having a thickness of 0.1 μm or greater, preferably approximately 1 μm, at least between the GaN layer 14 and the light emitting layer 18. Provision on the light emitting layer 18 of an additional p-SLS layer 20 having a thickness 0.1 μm or greater so that light is enclosed within the light emitting layer 18 can further improve the light emitting efficiency.

It should be noted that the average Al composition of the n-SLS layer 16 in the above embodiment is 0.1, and, in such a case, an AlGaN layer 16 having a thickness 0.1 μm or greater is required, as described above. An n-SLS layer 16 having smaller average Al composition has a larger refractive index. Therefore, configuration with an n-SLS layer 16 having smaller average AL composition reduces a difference in a refractive index between the n-SLS layer 16 and the light emitting layer 18. That is, when the Al composition of an n-SLS layer 16 is small, an n-SLS layer 16 must be formed thicker. For example, it is observed that, for average Al composition 0.05 of an n-SLS layer 16, the light emitting efficiency is improved when the n-SLS layer's 16 thickness is approximately 0.3 μm or greater. In other words, the thickness of the n-SLS layer 16 (or the p-SLS layer 20) is determined according to its average Al composition, and, generally, must be thicker for a smaller average Al composition.

It should be noted that an AlInGaN layer may be used in the place of the AlGaN layer 16 in this embodiment. Alternatively, an SLS layer containing AlInGaN may be used in the place of the AlGaN layer 16.

What is claimed is:

1. A GaN-based light emitting device, comprising:
a substrate;
a GaN layer formed on the substrate;
a light emitting layer formed on the GaN layer; and
a GaN-based layer formed between the GaN layer and the light emitting layer and having a refractive index smaller than a refractive index of the light emitting layer.

2. The GaN-based light emitting device according to claim 1, further comprising:
a second GaN-based layer formed on the light emitting layer and having a refractive index smaller than a refractive index of the light emitting layer.

3. The GaN-based light emitting device according to claim 1, wherein a thickness of the GaN-based layer is 0.1 μm or greater.

4. The GaN-based light emitting device according to claim 1, wherein the light emitting layer has a stacking structure constituting of an AlGaN layer and a GaN layer.

5. The GaN-based light emitting device according to claim 1, wherein the GaN-based layer has a stacking structure constituting of an AlGaN layer and a GaN layer.

6. The GaN-based light emitting device according to claim 1, wherein the GaN-based layer is an n-SLS layer doped with donor and constituting of alternately stacked AlGaN layer and GaN layer.

7. The GaN-based light emitting device according to claim 2, wherein a thickness of the second GaN-based layer is 0.1 μm or greater.

8. The GaN-based light emitting device according to claim 2, wherein the second GaN-based layer has a stacking structure constituting of an AlGaN layer and a GaN layer.

9. The GaN-based light emitting device according to claim 2, wherein the second GaN-based layer is a p-SLS layer doped with acceptor and constituting of alternately stacked AlGaN layer and GaN layer.

10. The GaN-based light emitting device according to claim 1, further comprising:
a p-GaN layer formed on the light emitting layer;
an n-electrode connected to the GaN layer; and
a p-electrode connected to the p-GaN layer.

11. A GaN-based light emitting device, comprising:
a substrate;
a GaN layer formed on the substrate;
a light emitting layer formed on the layer;
a GaN-based layer formed between the GaN layer and the light emitting layer and having Al composition larger than Al composition of the light emitting layer.

12. The GaN-based light emitting device according to claim 11, further comprising:
a second GaN-based layer formed on the light emitting layer and having Al composition larger than Al composition of the light emitting layer.

13. The GaN-based light emitting device according to claim 11, wherein a thickness of the GaN-based layer is 0.1 μm or greater.

14. The GaN-based light emitting device according to claim 11, wherein the light emitting layer has a stacking structure constituting of an AlGaN layer and a GaN layer.

15. The GaN-based light emitting device according to claim 11, wherein the GaN-based layer has a stacking structure constituting of an AlGaN layer and a GaN layer.

16. The GaN-based light emitting device according to claim 16, wherein the GaN-based layer is an n-SLS layer doped with donor and having a stacking structure constituting of an AlGaN layer and a GaN layer.

17. The GaN-based light emitting device according to claim 12, wherein the second GaN-based layer has a stacking structure constituting of an AlGaN layer and a GaN layer.

18. The GaN-based light emitting device according to claim 12, wherein the second GaN-based layer is a p-SLS layer doped with accepter and having a stacking structure comprising alternately stacked AlGaN layer and GaN layer.

19. A GaN-based light emitting device according to claim 11, further comprising:
a p-GaN layer formed on the light emitting layer;
an n-electrode connected to the GaN layer; and
a p-electrode connected to the p-GaN layer.
